(19) United States
(12) Patent Application Publication
(10) Pub. No.: US 2026/0231400 A1
(43) Pub. Date: Aug. 6, 2026

(54) 3D STACKED SEMICONDUCTOR DEVICE AND MANUFACTURING METHOD THEREFOR, 3D MEMORY, AND ELECTRONIC DEVICE

(71) Applicant: BEIJING SUPERSTRING ACADEMY OF MEMORY TECHNOLOGY, Beijing (CN)

(72) Inventors: Wenhua Gui, Beijing (CN); Xiangsheng Wang, Beijing (CN); Jin Dai, Beijing (CN); Guilei Wang, Beijing (CN); Xuezheng Ai, Beijing (CN); Shujuan Mao, Beijing (CN); Wei Yu, Beijing (CN)

(73) Assignee: BEIJING SUPERSTRING ACADEMY OF MEMORY TECHNOLOGY, Beijing (CN)

(21) Appl. No.: 19/150,221

(22) PCT Filed: Jun. 7, 2023
(86) PCT No.: PCT/CN2023/098869

§ 371 Date: Jul. 23, 2025

(30) Foreign Application Priority Data
Feb. 8, 2023 (CN) 202310080910.4

(51) Int. Cl. H10B 12/00; H10D 64/27

(52) U.S. Cl. CPC H10B 12/488; H10B 12/03; H10B 12/05; H10B 12/482; H10D 64/514; H10D 64/518

(57) ABSTRACT

A 3D stacked semiconductor device and a manufacturing method therefor, a 3D memory, and an electronic device. The 3D stacked semiconductor device includes a plurality of transistors and a word line (40). The plurality of transistors are distributed on different layers, stacked in a direction perpendicular to a substrate (20) and distributed periodically. A transistor includes a gate electrode (26), a semiconductor layer (23) surrounding the side wall of the gate electrode (26), and a gate insulating layer (24) arranged between the side wall of the gate electrode (26) and the semiconductor layer (23). The gate electrode (26) extends in the direction perpendicular to the substrate (20). The gate electrode (26) of each transistor is a part of the word line (40); and the plurality of semiconductor layers (23) of the plurality of transistors are arranged at intervals and disconnected.

### CROSS-REFERENCE TO RELATED APPLICATIONS

The present application is a U.S. National Phase Entry of International Application No. PCT/CN2023/098869 having an international filing date of Jun. 7, 2023, which claims priority to a Chinese Patent application No. 202310080910.4 filed to the CNIPA on Feb. 8, 2023, and entitled “3D Stacked Semiconductor Device and Manufacturing Method Therefor, 3D Memory, and Electronic Device”. Contents of the above-identified applications are incorporated in the present disclosure by reference.

### TECHNICAL FIELD

Embodiments of the present disclosure relate to, but are not limited to, the field of semiconductor devices, in particular to a 3D stacked semiconductor device, a manufacturing method therefor, a 3D memory and an electronic device.

### BACKGROUND

With the development of Dynamic Random Access Memory (DRAM) technology, in order to obtain higher storage capacitance, lower leakage and higher integration, DRAM memory is gradually developing to three-dimensional (3D) structure.

### SUMMARY

The following is a summary of the subject matter described in detail in this disclosure. This summary is not intended to limit the scope of protection of the present application.

An embodiment of the present disclosure provides a method for manufacturing a 3D stacked semiconductor device. The 3D stacked semiconductor device includes a plurality of transistors distributed in different layers, stacked in a direction perpendicular to a substrate and distributed periodically, and a word line. A transistor includes a gate electrode, a semiconductor layer surrounding a side wall of the gate electrode, and a gate insulating layer disposed between the side wall of the gate electrode and the semiconductor layer.

The method for manufacturing the 3D stacked semiconductor device includes:
forming a stacked structure composed of insulating layers and conductive layers that are alternately stacked on the substrate; wherein the conductive layers include an electrode pattern, the electrode pattern includes a bit line to be formed and a plurality of branches located on at least one side of the bit line, each branch includes a first electrode and a second electrode of the transistor; and a gap between electrode patterns of any adjacent conductive layers is filled with an isolation layer;
forming through-holes passing through the stacked structure by etching, such that the through-holes in the conductive layers are smaller than the through-holes in the insulating layers;
laterally etching the conductive layers in the through-holes to disconnect the first electrode and the second electrode of each transistor;
laterally etching an exposed isolation layer in the through-holes such that the through-holes extend only into the isolation layer between two adjacent through-holes and form an extension portion passing through the isolation layer, and filling a sacrificial layer in the extension portion of the through-holes;
sequentially depositing a semiconductor thin film and the gate insulating layer on side walls of the through-holes, and filling the word line in the through-holes; and
etching the sacrificial layer in the extension portion of the through-holes in a region between two adjacent through-holes, such that the side walls of the through-holes alternately expose the semiconductor thin film and the sacrificial layer in the direction perpendicular to the substrate; and etching and removing the semiconductor thin film exposed from the side walls of the through-holes, such that the remaining semiconductor thin film constitutes the semiconductor layer of the transistor.

Exemplarily, the step of, forming the stacked structure composed of the insulating layers and the conductive layers that are alternately stacked on the substrate, may include: providing the substrate, sequentially and alternately depositing a first insulating thin film and a conductive thin film on the substrate, and forming the stacked structure by patterning; wherein the stacked structure includes a stack of the insulating layers and the conductive layers that are alternately disposed.

The branches of the electrode pattern may include a plurality of spaced first sub-portions and a plurality of spaced second sub-portions, the plurality of spaced first sub-portions and the plurality of spaced second sub-portions are respectively located on two sides of the bit line and connected to the bit line. One end of a first sub-portion away from the bit line is exposed, one end of a second sub-portion away from the bit line is exposed, the first sub-portions and the second sub-portions are subsequently disconnected from the bit line to form the first electrodes of transistors, and the bit line is shared as the second electrodes of the transistors. The isolation layer may be formed by the first insulating thin film and extend in the direction perpendicular to the substrate.

Exemplarily, the step of, forming the through-holes passing through the stacked structure by etching, such that the through-holes in the conductive layers are smaller than the through-holes in the insulating layers, may include: etching the stacked structure to form the through-holes passing through the conductive layers of the stacked structure, such that entire side walls of the through-holes in the conductive layers expose only the conductive layers; and laterally etching the insulating layers in the through-holes such that the through-holes in the conductive layers are smaller than the through-holes in the insulating layers.

Exemplarily, the step of, laterally etching the conductive layers in the through-holes to disconnect the first electrode and the second electrode of each transistor, may include: laterally etching the conductive layers in the through-holes, such that the side walls of the through-holes in each conductive layer expose the conductive layer and the first insulating thin film simultaneously. The through-holes cause the conductive layers to form at least one pair of a first conductive portion and a second conductive portion separated from each other, and the first conductive portion and the second conductive portion respectively serve as a first electrode and a second electrode of the transistor.

Exemplarily, the step of, laterally etching the exposed isolation layer in the through-holes such that the through-holes extend only into the isolation layer between two adjacent through-holes and form the extension portion passing through the isolation layer, and filling the sacrificial layer in the extension portion of the through-holes, may include: depositing a sacrificial layer thin film on inner walls of the through-holes and filling a second insulating thin film in the through-holes; etching and removing the sacrificial layer thin film on at least a part of the side walls of the through-holes and laterally etching the isolation layer formed by the exposed first insulating thin film in the through-holes, such that the through-holes extend only into the isolation layer between two adjacent through-holes and form the extension portion passing through the isolation layer, and filling the sacrificial layer thin film in the through-holes to form the sacrificial layer; and etching and removing the second insulating thin film in the through-holes, and removing the sacrificial layer on the side walls of the through-holes, such that the side walls of the through-holes in the insulating layers expose the insulating layers and the sacrificial layer simultaneously, and the side walls of the through-holes in the conductive layers expose the first conductive portion and the second conductive portion of the conductive layers and the sacrificial layer.

Exemplarily, the method for manufacturing the 3D stacked semiconductor device may further include: before etching the stacked structure to form the through-holes, performing the following process: sequentially depositing a dielectric layer and a second plate on the exposed end of the first sub-portion and the exposed end of the second sub-portion. The dielectric layer covers the exposed end of the first sub-portion and the exposed end of the second sub-portion, the second plate covers the dielectric layer, and the first sub-portion or the second sub-portion and the second plate constitute a capacitor.

Exemplarily, the step of, sequentially depositing the semiconductor thin film and the gate insulating layer on the side walls of the through-holes, and filling the word line in the through-holes, may include: sequentially depositing the semiconductor thin film and a gate insulating thin film on the side walls of the through-holes, the semiconductor thin film being in contact with the first electrode and the second electrode of the transistor, and filling a gate electrode thin film in the through-holes, the gate electrode thin film forming the word line.

Exemplarily, the step of, etching the sacrificial layer in the extension portion of the through-holes in the region between two adjacent through-holes, such that the side walls of the through-holes alternately expose the semiconductor thin film and the sacrificial layer in the direction perpendicular to the substrate; and etching and removing the semiconductor thin film exposed from the side walls of the through-holes, such that the remaining semiconductor thin film constitutes the semiconductor layer of the transistor, may include: etching the sacrificial layer in the extension portion of the through-holes in the region between two adjacent through-holes, such that the side walls of the through-holes in the insulating layers expose the semiconductor thin film, and the side walls of the through-holes in the conductive layers expose the sacrificial layer; and etching and removing the semiconductor thin film in the through-holes in the insulating layers, such that the remaining semiconductor thin film between adjacent insulating layers constitutes the semiconductor layer of the transistor, semiconductor layers corresponding to two adjacent transistors are disconnected from each other, and the gate insulating thin film forms the gate insulating layer of each transistor.

Exemplarily, the step of, etching the stacked structure to form the through-holes passing through the conductive layers of the stacked structure, may include: dry-etching the stacked structure to form the through-holes passing through the conductive layers of the stacked structure, such that entire side walls of the through-holes in the conductive layers expose only the conductive layers.

Exemplarily, the step of, laterally etching the insulating layers in the through-holes, may include: laterally etching the insulating layers in the through-holes by wet etching, such that the through-holes in the conductive layers are smaller than the through-holes in the insulating layers.

Exemplarily, the step of, laterally etching the conductive layers in the through-holes, may include: laterally etching the conductive layers in the through-holes by wet etching, such that the side walls of the through-holes in each conductive layer expose the conductive layer and the first insulating thin film simultaneously.

An embodiment of the present disclosure provides a 3D stacked semiconductor device obtained by the manufacturing method as provided in the above embodiments of the present disclosure. The gate electrode extends in the direction perpendicular to the substrate; and a plurality of semiconductor layers of the plurality of transistors are arranged at intervals and disconnected.

The word line passes through the different layers, the word line includes a word line body and protrusions arranged on the word line body, the word line body extends in the direction perpendicular to the substrate, and the protrusions of the word line extend between the semiconductor layers arranged at intervals. The gate electrode of each transistor is a part of the word line, and the plurality of semiconductor layers are distributed in different regions of a side wall of the word line body.

Exemplarily, the semiconductor device may further include: the insulating layers and the conductive layers alternately and sequentially distributed from bottom to top in the direction perpendicular to the substrate; and the through-holes passing through the insulating layers and the conductive layers. The word line, the gate insulating layer surrounding a side wall of the word line, and the plurality of semiconductor layers surrounding different regions of a side wall of the gate insulating layer and extending in the direction perpendicular to the substrate are sequentially distributed from inner to outer in the through-holes.

The plurality of semiconductor layers are disconnected at side walls of the insulating layers, and the protrusions of the word line extend into the insulating layers. A conductive layer includes a first conductive portion and a second conductive portion spaced apart from each other, the first conductive portion and the second conductive portion are a source electrode and a drain electrode of the transistor, respectively, and each semiconductor layer is in contact with a source electrode and a drain electrode of the conductive layer in a corresponding layer.

Exemplarily, a pore diameter of a first region of the through-holes corresponding to the conductive layers is smaller than a pore diameter of a second region of the through-holes corresponding to the insulating layers. Only side walls of the insulating layers are exposed in the through-holes, and side walls and partial regions of upper and lower surfaces of the conductive layers are exposed in the through-holes. The semiconductor layers are distributed at least on the side walls of the conductive layers.

Exemplarily, the gate electrode is a part of the word line body, and the semiconductor layer at least surrounds between two adjacent protrusions.

Exemplarily, the transistor includes a first electrode and a second electrode, and the first electrode and the second electrode are a source electrode and a drain electrode of the transistor, respectively, and a semiconductor layer extends onto at least a part of a side wall of the first electrode of the transistor.

Exemplarily, a channel between the source electrode and the drain electrode of one of the transistors is a horizontal channel.

An embodiment of the present disclosure provides a 3D memory obtained by the manufacturing method as provided in the above embodiments of the present disclosure. The 3D memory includes a plurality of layers of memory cells stacked in a direction perpendicular to a substrate, and a word line passing through the memory cells in different layers. The memory cells include the transistors; and semiconductor layers of the transistors of the memory cells in at least some adjacent layers are arranged at intervals in the direction perpendicular to the substrate. The word line includes a word line body and protrusions arranged on the word line body, the word line body extends in the direction perpendicular to the substrate, the semiconductor layers arranged at intervals are disconnected from each other, and the protrusions of the word line extend between the semiconductor layers arranged at intervals.

Exemplarily, an insulating layer is exposed between the semiconductor layers arranged at intervals, the insulating layer is a gate insulating layer located between the gate electrode and the semiconductor layer, and gate insulating layers of the transistors in a same column in the different layers have an integral structure.

Exemplarily, the gate electrode may be a part of the word line body, and the semiconductor layer at least surrounds between two adjacent protrusions.

An embodiment of the present disclosure provides an electronic device including the 3D stacked semiconductor device as provided by the above embodiments of the present disclosure, or the 3D memory as provided by the above embodiments of the present disclosure.

Other aspects may be understood upon reading and understanding the drawings and detailed description.

### BRIEF DESCRIPTION OF DRAWINGS

Accompanying drawings are used for providing understanding of technical schemes of the present disclosure, and form a part of the specification. They are used for explaining the technical schemes of the present disclosure together with the embodiments of the present disclosure, but do not form a limitation on the technical schemes of the present disclosure.

FIG. 1 is a process flowchart of a method for manufacturing a 3D stacked semiconductor device according to an exemplary embodiment of the present disclosure.

FIG. 2 is a schematic diagram after a stacked structure is formed by using a method for manufacturing a 3D stacked semiconductor device according to an exemplary embodiment of the present disclosure.

FIG. 3A is a cross-sectional view in a direction parallel to a substrate after a conductive layer is formed by using a method for manufacturing a 3D stacked semiconductor device according to an exemplary embodiment of the present disclosure.

FIG. 3B is a cross-sectional view of the structure shown in FIG. 3A along a direction bb′.

FIG. 4A is a cross-sectional view in a direction parallel to a substrate after an insulating layer of a capacitor region is removed by using a method for manufacturing a 3D stacked semiconductor device according to an exemplary embodiment of the present disclosure.

FIG. 4B is a cross-sectional view of the structure shown in FIG. 4A along a direction aa′.

FIG. 5A is a cross-sectional view in a direction parallel to a substrate after a second plate is formed by using a method for manufacturing a 3D stacked semiconductor device according to an exemplary embodiment of the present disclosure.

FIG. 5B is a cross-sectional view of the structure shown in FIG. 5A along a direction aa′.

FIG. 6A is a cross-sectional view in a direction parallel to a substrate after a through-hole K1 is formed by using a method for manufacturing a 3D stacked semiconductor device according to an exemplary embodiment of the present disclosure.

FIG. 6B is a cross-sectional view of the structure shown in FIG. 6A along a direction aa′.

FIG. 6C is a cross-sectional view of the structure shown in FIG. 6A along a direction bb′.

FIG. 7A is a cross-sectional view in the direction aa′ in FIG. 6A after the through-hole K1 is enlarged for the first time by using a method for manufacturing a 3D stacked semiconductor device according to an exemplary embodiment of the present disclosure.

FIG. 7B is a cross-sectional view of the structure shown in FIG. 7A along a direction bb′ shown in FIG. 6A.

FIG. 8A is a cross-sectional view in a direction parallel to a substrate after the through-hole K1 is enlarged for the second time by using a method for manufacturing a 3D stacked semiconductor device according to an exemplary embodiment of the present disclosure.

FIG. 8B is a cross-sectional view of the structure shown in FIG. 8A along a direction bb′.

FIG. 9A is a cross-sectional view in a direction parallel to a substrate after a sacrificial layer is formed by using a method for manufacturing a 3D stacked semiconductor device according to an exemplary embodiment of the present disclosure.

FIG. 9B is a cross-sectional view of the structure shown in FIG. 9A along a direction aa′.

FIG. 9C is a cross-sectional view of the structure shown in FIG. 9A along a direction bb′.

FIG. 10A is a cross-sectional view in a direction parallel to a substrate after a gate electrode is formed by using a method for manufacturing a 3D stacked semiconductor device according to an exemplary embodiment of the present disclosure.

FIG. 10B is a cross-sectional view of the structure shown in FIG. 10A along a direction aa′.

FIG. 10C is a cross-sectional view of the structure shown in FIG. 10A along a direction bb′.

FIG. 11A is a cross-sectional view of a 3D stacked semiconductor device in a direction parallel to a substrate according to an exemplary embodiment of the present disclosure.

FIG. 11B is a cross-sectional view of the semiconductor device shown in FIG. 11A along a direction aa′.

FIG. 11C is a cross-sectional view of the semiconductor device shown in FIG. 11A along a direction bb′.

FIG. 12A is a cross-sectional view of a 3D memory in a direction parallel to a substrate according to an exemplary embodiment of the present disclosure.

FIG. 12B is a cross-sectional view of the 3D memory shown in FIG. 12A along a direction aa′.

FIG. 12C is a cross-sectional view of the 3D memory shown in FIG. 12A along a direction bb′.

### DETAILED DESCRIPTION

To make the objectives, technical schemes, and advantages of the present disclosure clearer, the embodiments of the present disclosure will be described in detail below in combination with the accompanying drawings. It should be noted that the embodiments and the features of the embodiments of the present disclosure may be arbitrarily combined with each other if there is no conflict.

An implementation of the present disclosure is not necessarily limited to dimensions shown in the drawings, and the shapes and sizes of the components in the drawings do not reflect actual scales. Further, the drawings schematically illustrate ideal examples, but implementations of the present disclosure are not limited to shapes or values shown in the drawings.

Ordinal numerals such as “first” and “second” in the present disclosure are provided to avoid confusion between constituent elements, but do not indicate any order, quantity or importance.

In the present disclosure, for convenience, words or expressions indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description of the specification and simplification of the description only, but do not indicate or imply that the referred device or element must have a particular orientation or is constructed and operated in a particular orientation, and therefore cannot be construed as limitations on the present disclosure. The positional relationship between the constituent elements is appropriately changed according to a direction in which various constituent elements are described. Therefore, the present disclose is not limited to the words or expressions described in the present disclosure, and replacement may be appropriately made according to the situation.

In the present disclosure, terms “mount”, “couple” and “connect” should be understood broadly, unless otherwise expressly specified and defined. For example, it may be a fixed connection, a detachable connection, or an integral connection; it may be a mechanical connection or an electrical connection; it may be a direct connection, an indirect connection through a middleware, or an internal communication between two elements. For those of ordinary skill in the art, specific meanings of the above terms in the present disclosure may be understood according to actual situations.

In the present disclosure, a transistor refers to an element including at least three terminals, i.e., a gate electrode, a drain electrode, and a source electrode. The transistor has a channel region between a drain electrode (drain electrode terminal, drain region, or drain) and a source electrode (source electrode terminal, source region, or source), and a current can flow through the drain electrode, the channel region, and the source electrode. In the present disclosure, the channel region refers to the region through which the current mainly flows.

In the present disclosure, a first electrode may be a drain electrode and a second electrode may be a source electrode, or the first electrode may be a source electrode and the second electrode may be a drain electrode. In cases that transistors with opposite polarities are used, or a current direction changes during operation of a circuit, or the like, functions of the “source electrode” and the “drain electrode” may sometimes be exchanged. Therefore, in the present disclosure, the “source electrode” and the “drain electrode” are interchangeable.

In the present disclosure, an “electrical connection” includes a case where the constituent elements are connected together by an element with a certain electrical effect. There is no special restriction on the “element with a certain electrical effect” as long as electrical signals between connected constituent elements may be sent and received. Examples of the “element with a certain electrical effect” include not only electrodes and wirings, but also include switching elements such as transistors, resistors, inductors, capacitors, and other elements having various functions, etc.

In the present disclosure, “parallel” refers to approximately parallel or almost parallel, for example, a state in which an angle formed by two straight lines is −10° or more and 10° or less, and therefore further includes a state in which the angle is −5° or more and 5° or less. In addition, “perpendicular” refers to approximately perpendicular, for example, a state in which an angle formed by two straight lines is 80° or more and 100° or less, and therefore further includes a state in which the angle is 85° or more and 95° or less.

In the present disclosure, “film” and “layer” may be interchanged with each other. For example, “conductive layer” may sometimes be replaced by “conductive film”. Similarly, “insulating film” may sometimes be replaced by “insulating layer”.

In the present disclosure, “A and B are arranged in a same layer” means that A and B are simultaneously formed by a same patterning process.

“A and B are of an integrated structure” in the embodiments of the present disclosure may mean that there is no distinct boundary interface, such as distinct faultage or gaps, viewed from the microstructure. Generally, connected film layers formed by patterning on one film layer are integrated. For example, A and B form one film layer using a same material and simultaneously form a structure with a connection relationship through a same patterning process.

In the present disclosure, a “pore diameter” is an average pore diameter obtained after measurement at a plurality of positions.

In an embodiment of the present disclosure, by etching and removing the semiconductor layer between transistors in different layers, the parasitic MOS can be reduced or eliminated, the stability of the device can be increased, and the influence of the etching process on the channel can be sufficiently reduced or eliminated, thereby ensuring the effective length of the channel.

The inventive concept realized by the process of the present disclosure mainly includes: obtaining vertical WL small holes on a stack of insulating layers and conductive layers by an etching method such as dry etching, and laterally etching the insulating layers by an etching method such as wet etching. The finally formed WL hole structure is characterized in that a pore diameter between two transistors (Field Effect Transistor (FET)) is larger than a pore diameter of the FET region. Then a sacrificial layer is deposited as an isolation on an exterior of the WL hole and on a side wall of the hole using the atomic layer deposition (ALD) method, and a semiconductor film layer (such as IGZO), a gate insulating layer (such as High-K dielectric film layer Al₂O₃) and metal gate material (such as ITO thin film) are sequentially deposited in the WL hole. Finally, the sacrificial layer which acts for isolation is etched from the outside of the WL hole by dry etching and wet etching. During this etching process, only the sacrificial layer between the two transistors and the semiconductor film layer inside are etched, and the sacrificial layer and the semiconductor layer in the channel region are not etched. This method can effectively remove parasitic MOS without affecting the effective length of the channel, thus improving the device stability.

Hereinafter, the inventive concept of the present disclosure will be described in detail.

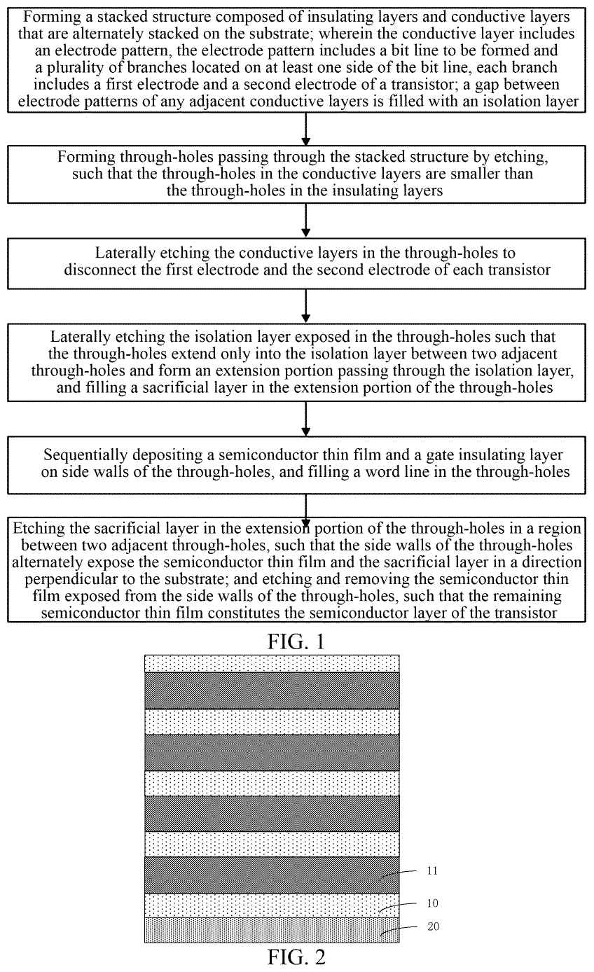

An embodiment of the disclosure provides a method for manufacturing a 3D stacked semiconductor device. FIG. 1 is a process flowchart of a method for manufacturing a 3D stacked semiconductor device according to an exemplary embodiment of the present disclosure. As shown in FIG. 1, in the present embodiment, the 3D stacked semiconductor device may include a plurality of transistors that are distributed in different layers, stacked in a direction perpendicular to a substrate and distributed periodically, and a word line. The transistor includes a gate electrode, a semiconductor layer surrounding a side wall of the gate electrode, and a gate insulating layer disposed between the side wall of the gate electrode and the semiconductor layer.

The method for manufacturing a 3D stacked semiconductor device includes:
forming a stacked structure composed of insulating layers and conductive layers that are alternately stacked on the substrate; wherein the conductive layers include an electrode pattern, the electrode pattern includes a bit line to be formed and a plurality of branches located on at least one side of the bit line, each branch includes a first electrode and a second electrode of the transistor; a gap between electrode patterns of any adjacent conductive layers is filled with an isolation layer;
forming through-holes passing through the stacked structure by etching, such that the through-holes in the conductive layers are smaller than the through-holes in the insulating layers;
laterally etching the conductive layers in the through-holes to disconnect the first electrode and the second electrode of each transistor;
laterally etching the exposed isolation layer in the through-holes such that the through-holes extend only into the isolation layer between two adjacent through-holes and form an extension portion passing through the isolation layer, and filling a sacrificial layer in the extension portion of the through-holes;
sequentially depositing a semiconductor thin film and a gate insulating layer on side walls of the through-holes, and filling the word line in the through-holes; and
etching the sacrificial layer in the extension portion of the through-holes in a region between two adjacent through-holes, such that the side walls of the through-holes alternately expose the semiconductor thin film and the sacrificial layer in a direction perpendicular to the substrate; and etching and removing the semiconductor thin film exposed from the side walls of the through-holes, such that the remaining semiconductor thin film constitutes the semiconductor layer of the transistor.

Exemplarily, the step of, forming a stacked structure composed of insulating layers and conductive layers that are alternately stacked on the substrate, may include: providing the substrate, sequentially and alternately depositing a first insulating thin film and a conductive thin film on the substrate, and forming a stacked structure by patterning. The stacked structure includes a stack of insulating layers and conductive layers that are alternately disposed.

Exemplarily, the branches of the electrode pattern may include a plurality of spaced first sub-portions and a plurality of spaced second sub-portions, and the plurality of spaced first sub-portions and the plurality of spaced second sub-portions are respectively located on two sides of the bit line and connected to the bit line. One end of the first sub-portion away from the bit line is exposed, one end of the second sub-portion away from the bit line is exposed, the first sub-portion and the second sub-portion are subsequently disconnected from the bit line to form a first electrode of a transistor, and the bit line is shared as a second electrode of the transistor.

Exemplarily, the isolation layer may be formed by the first insulating thin film and extend in a direction perpendicular to the substrate.

Exemplarily, the step of, forming through-holes passing through the stacked structure by etching, such that the through-holes in the conductive layers are smaller than the through-holes in the insulating layers, may include: etching the stacked structure to form through-holes passing through the conductive layers of the stacked structure, such that the entire side wall of the through-hole in the conductive layer exposes only the conductive layer; and laterally etching the insulating layers in the through-holes such that the through-holes in the conductive layers are smaller than the through-holes in the insulating layers.

Exemplarily, the step of, laterally etching the conductive layers in the through-holes to disconnect the first electrode and the second electrode of each transistor, may include: laterally etching the conductive layers in the through-holes, such that the side wall of the through-hole of each conductive layer exposes the conductive layer and the first insulating thin film simultaneously. The through-hole causes the conductive layer to form at least one pair of a first conductive portion and a second conductive portion separated from each other, and the first conductive portion and the second conductive portion respectively serve as a first electrode and a second electrode of the transistor.

Exemplarily, the step of, sequentially depositing a semiconductor thin film and a gate insulating layer on side walls of the through-holes, and filling the word line in the through-holes, may include: sequentially depositing a semiconductor thin film and a gate insulating thin film on the side walls of the through-holes, the semiconductor thin film being in contact with the first electrode and the second electrode of the transistor, and filling a gate electrode thin film in the through-holes, the gate electrode thin film forming the word line.

Exemplarily, the step of, etching the sacrificial layer in the extension portion of the through-holes in a region between two adjacent through-holes, such that the side walls of the through-holes alternately expose the semiconductor thin film and the sacrificial layer in a direction perpendicular to the substrate; and etching and removing the semiconductor thin film exposed from the side walls of the through-holes, such that the remaining semiconductor thin film constitutes the semiconductor layer of the transistor, may include: etching the sacrificial layer in the extension portion of the through-holes in a region between two adjacent through-holes, such that the side walls of the through-holes in the insulating layers expose the semiconductor thin film, and the side walls of the through-holes in the conductive layers expose the sacrificial layer; and etching and removing the semiconductor thin film in the through-holes in the insulating layers, such that the remaining semiconductor thin film between adjacent insulating layers constitutes the semiconductor layer of the transistor, semiconductor layers corresponding to two adjacent transistors are disconnected from each other, and the gate insulating thin film forms a gate insulating layer of each transistor.

Exemplarily, the method for manufacturing a 3D stacked semiconductor device includes:
S10: Providing a substrate, sequentially and alternately depositing a first insulating thin film and a conductive thin film on the substrate, and forming a stacked structure by patterning. The stacked structure includes a stack of insulating layers and conductive layers that are alternately disposed, the conductive layer includes an electrode pattern and the electrode pattern includes a plurality of spaced first sub-portions, a plurality of spaced second sub-portions, and a bit line connecting the first sub-portions and the second sub-portions. The plurality of spaced first sub-portions and the plurality of spaced second sub-portions are respectively located on two sides of the bit line. One end of the first sub-portion away from the bit line is exposed, one end of the second sub-portion away from the bit line is exposed, the first sub-portions and the second sub-portions are subsequently disconnected from the bit line to form first electrodes of transistors, and the bit line is shared as second electrodes of the transistors. A gap between electrode patterns of any adjacent conductive layers is filled with an isolation layer formed by a first insulating thin film and extending in a direction perpendicular to the substrate.
S20: Etching the stacked structure to form through-holes passing through the conductive layers of the stacked structure, such that the entire side walls of the through-holes in the conductive layers expose only the conductive layers, and laterally etching the insulating layers in the through-holes such that the through-holes in the conductive layers are smaller than the through-holes in the insulating layers.
S30: Laterally etching the conductive layers in the through-holes, such that side walls of the through-holes in each conductive layer expose the conductive layer and the first insulating thin film simultaneously, and the through-holes cause the conductive layer to form at least one pair of a first conductive portion and second a conductive portion separated from each other at this time.
S40: Laterally etching the isolation layer formed by the exposed first insulating thin film in the through-holes, such that the through-holes extend only into the isolation layer between two adjacent through-holes and forms an extension portion passing through the isolation layer, and filling a sacrificial layer thin film in the extension portion of the through-holes to form a sacrificial layer.
S50: Sequentially depositing a semiconductor thin film and a gate insulating thin film on the side walls of the through-holes, the semiconductor thin film being in contact with the first conductive portion and the second conductive portion, and filling a gate electrode thin film in the through-holes, the gate electrode thin film forming the word line.
S60: Etching the sacrificial layer in the extension portion of the through-holes, such that the side walls of the through-holes in the insulating layers expose the semiconductor thin film, and the side walls of the through-holes in the conductive layers expose the sacrificial layer; and etching and removing the semiconductor thin film in the through-holes in the insulating layers, such that the remaining semiconductor thin film between the adjacent insulating layers constitutes the semiconductor layer of the transistor, the semiconductor layers corresponding to two adjacent transistors are disconnected from each other, and the gate insulating thin film forms a gate insulating layer of each transistor.

Exemplarily, the step of, laterally etching the isolation layer formed by the exposed first insulating thin film in the through-holes, such that the through-holes extend only into the isolation layer between two adjacent through-holes and forms an extension portion passing through the isolation layer, and filling a sacrificial layer thin film in the extension portion of the through-holes to form a sacrificial layer, may include: depositing a sacrificial layer thin film on inner walls of the through-holes and filling a second insulating thin film in the through-holes; etching and removing the sacrificial layer thin film on at least a part of the side walls of the through-holes and laterally etching the isolation layer formed by the exposed first insulating thin film in the through-holes, such that the through-holes extend only into the isolation layer between two adjacent through-holes and forms an extension portion passing through the isolation layer, and filling the sacrificial layer thin film in the through-holes to form a sacrificial layer; and etching and removing the second insulating thin film in the through-holes, and removing the sacrificial layer on the side walls of the through-holes, such that the side walls of the through-holes in the insulating layers expose the insulating layers and the sacrificial layer simultaneously, and the side walls of the through-holes in the conductive layers expose the first conductive portion and the second conductive portion of the conductive layer and the sacrificial layer.

Exemplarily, the method for manufacturing the 3D stacked semiconductor device may further include: before etching the stacked structure to form the through-holes, performing the following process: sequentially depositing a dielectric layer and a second plate on an exposed end of the first sub-portion and an exposed end of the second sub-portion. The dielectric layer covers the exposed end of the first sub-portion and the exposed end of the second sub-portion, the second plate covers the dielectric layer, and the first sub-portion or the second sub-portion and the second plate constitute a capacitor.

Exemplarily, the step of, etching the stacked structure to form through-holes passing through conductive layers of the stacked structure, may include: dry-etching the stacked structure to form through-holes passing through the conductive layers of the stacked structure, such that the entire side walls of the through-holes in the conductive layers expose only the conductive layers.

Exemplarily, the step of, laterally etching the insulating layers in the through-holes, may include: laterally etching the insulating layers in the through-holes by wet etching, such that the through-holes in the conductive layers are smaller than the through-holes in the insulating layers.

Exemplarily, the step of, laterally etching the conductive layers in the through-holes, may include: laterally etching the conductive layers in the through-holes by wet etching, such that the side walls of the through-holes in each conductive layer expose the conductive layer and the first insulating thin film simultaneously.

Hereinafter, the technical scheme according to embodiments of the present disclosure will be further described by the manufacturing process of the 3D stacked semiconductor device of the exemplary embodiments. A “patterning process” mentioned in the embodiments includes film layer deposition, photoresist coating, mask exposure, development, etching, photoresist stripping, and other treatments, and is a mature manufacturing process in related technologies. A “photolithography process” in the embodiments includes film layer coating, mask exposure, and development, and is a mature manufacturing process in the related technologies. Known processes such as sputtering, evaporation, chemical vapor deposition may be used for the deposition, known coating processes may be used for the coating, and known approaches may be used for etching, which are not specifically limited here. In description of the embodiments, it should be understood that a “thin film” refers to a layer of thin film made of a certain material on a substrate using a deposition or coating process. If the “thin film” does not need a patterning process or photolithography process during the whole manufacturing process, the “thin film” may also be called a “layer”. If the “thin film” needs a patterning process or photolithography process during the whole manufacturing process, it is called a “thin film” before the patterning process and a “layer” after the patterning process. The “layer” after the patterning process or photolithography process contains at least one “pattern”.

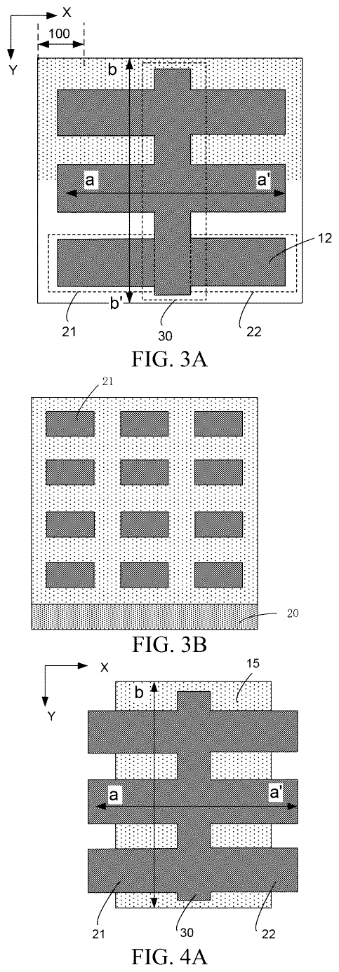

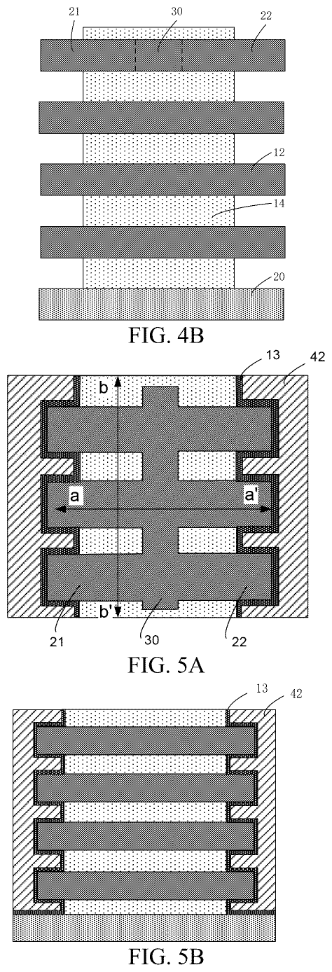

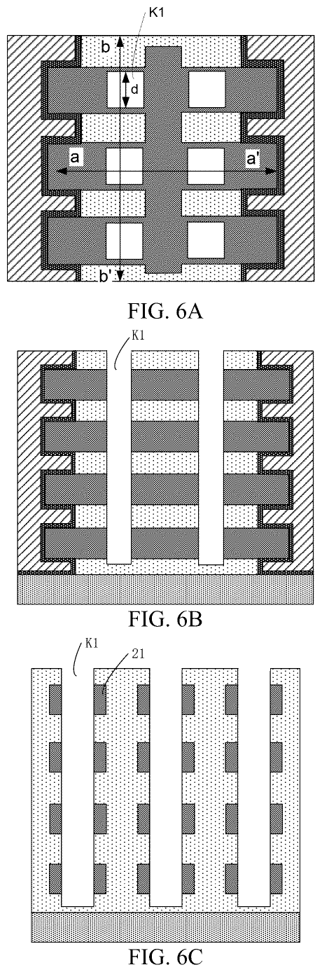

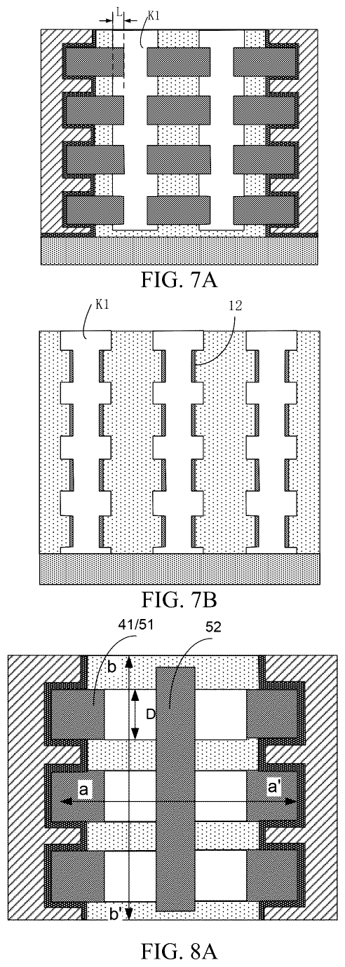

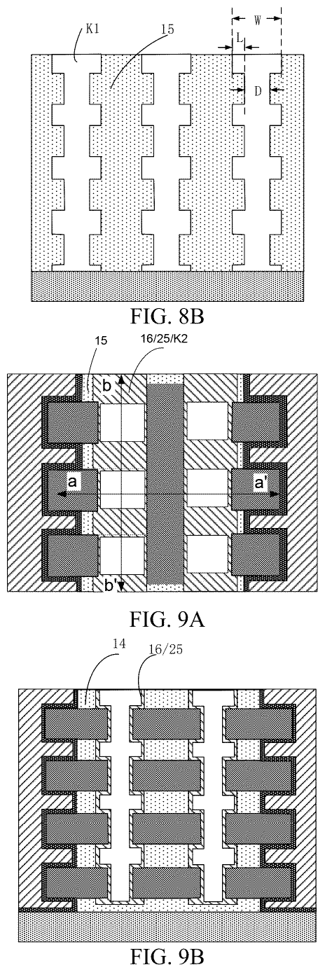

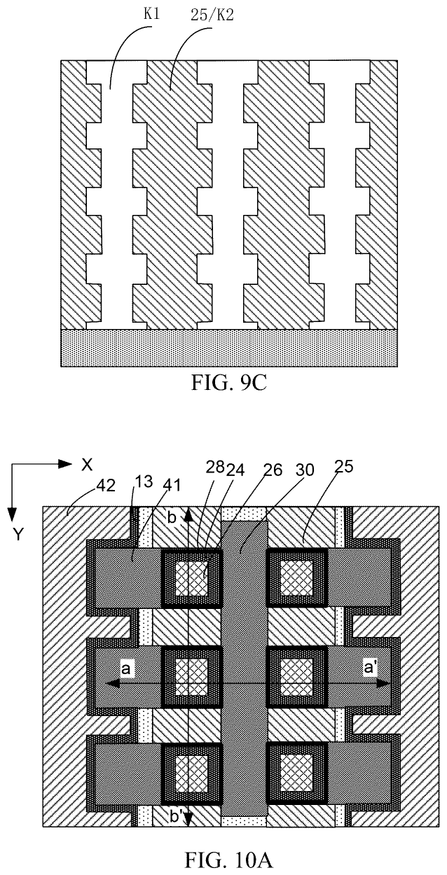

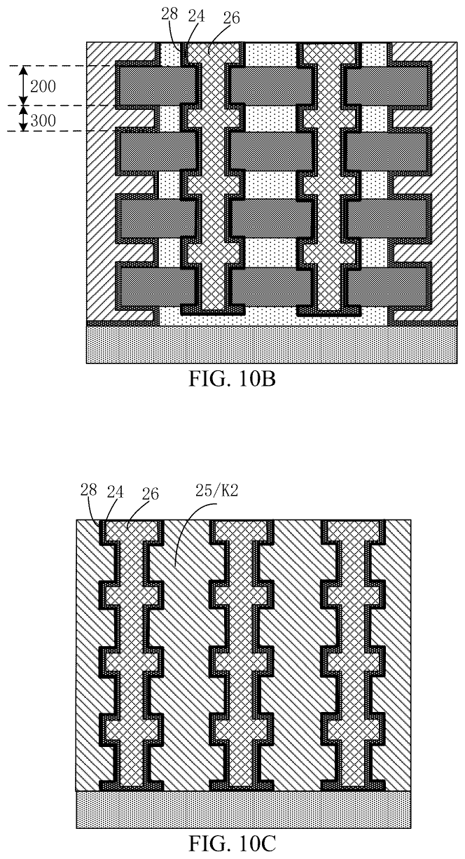

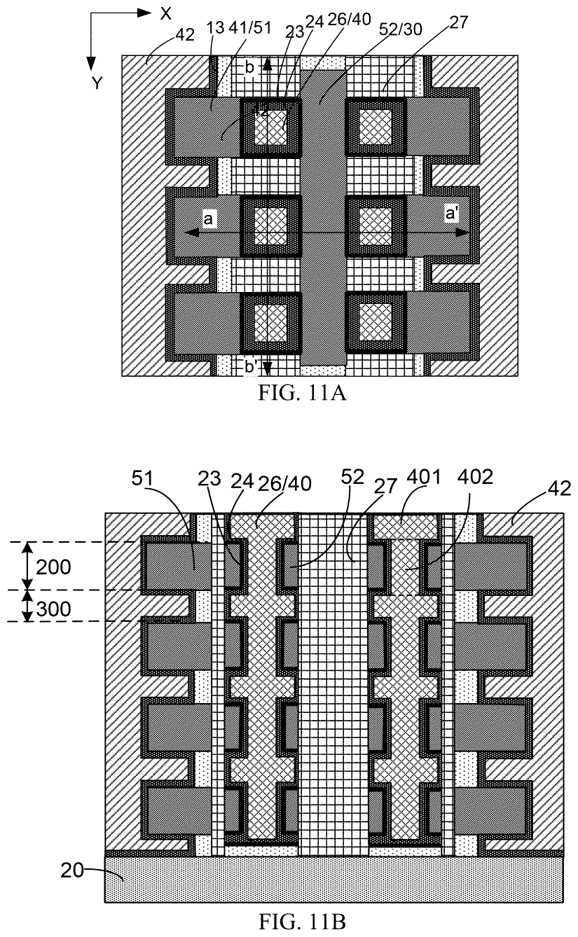

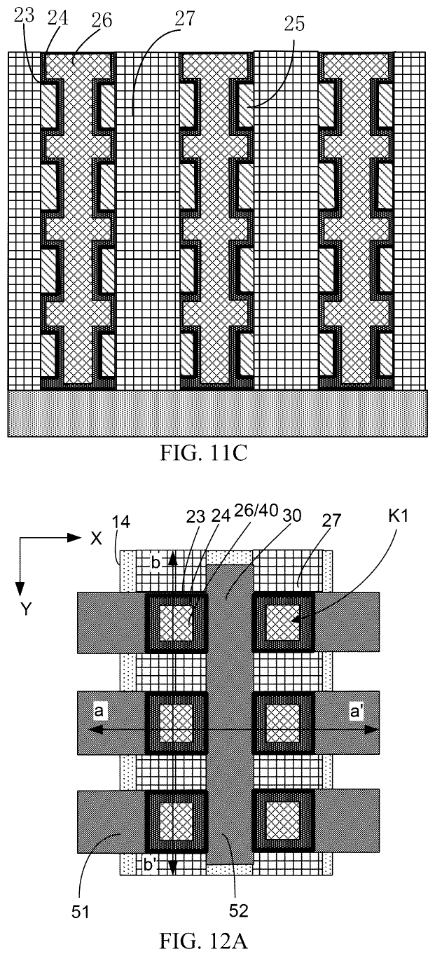

FIG. 2 is a schematic diagram after a stacked structure is formed by using a method for manufacturing a 3D stacked semiconductor device according to an exemplary embodiment of the present disclosure. FIG. 3A is a cross-sectional view in a direction parallel to a substrate after a conductive layer is formed by using a method for manufacturing a 3D stacked semiconductor device according to an exemplary embodiment of the present disclosure. FIG. 3B is a cross-sectional view of the structure shown in FIG. 3A along a direction bb′. FIG. 4A is a cross-sectional view in a direction parallel to a substrate after an insulating layer of a capacitor region is removed by using a method for manufacturing a 3D stacked semiconductor device according to an exemplary embodiment of the present disclosure. FIG. 4B is a cross-sectional view of the structure shown in FIG. 4A along a direction aa′. FIG. 5A is a cross-sectional view in a direction parallel to a substrate after a second plate is formed by using a method for manufacturing a 3D stacked semiconductor device according to an exemplary embodiment of the present disclosure. FIG. 5B is a cross-sectional view of the structure shown in FIG. 5A along a direction aa′. FIG. 6A is a cross-sectional view in a direction parallel to a substrate after a through-hole K1 is formed by using a method for manufacturing a 3D stacked semiconductor device according to an exemplary embodiment of the present disclosure. FIG. 6B is a cross-sectional view of the structure shown in FIG. 6A along a direction aa′. FIG. 6C is a cross-sectional view of the structure shown in FIG. 6A along a direction bb′. FIG. 7A is a cross-sectional view in the direction aa′ in FIG. 6A after the through-hole K1 is enlarged for the first time by using a method for manufacturing a 3D stacked semiconductor device according to an exemplary embodiment of the present disclosure. FIG. 7B is a cross-sectional view of the structure shown in FIG. 7A along the direction bb′ shown in FIG. 6A. FIG. 8A is a cross-sectional view in a direction parallel to a substrate after the through-hole K1 is enlarged for the second time by using a method for manufacturing a 3D stacked semiconductor device according to an exemplary embodiment of the present disclosure. FIG. 8B is a cross-sectional view of the structure shown in FIG. 8A along a direction bb′. FIG. 9A is a cross-sectional view in a direction parallel to a substrate after a sacrificial layer is formed by using a method for manufacturing a 3D stacked semiconductor device according to an exemplary embodiment of the present disclosure. FIG. 9B is a cross-sectional view of the structure shown in FIG. 9A along a direction aa′. FIG. 9C is a cross-sectional view of the structure shown in FIG. 9A along a direction bb′. FIG. 10A is a cross-sectional view in a direction parallel to a substrate after a gate electrode is formed by using a method for manufacturing a 3D stacked semiconductor device according to an exemplary embodiment of the present disclosure. FIG. 10B is a cross-sectional view of the structure shown in FIG. 10A along a direction aa′. FIG. 10C is a cross-sectional view of the structure shown in FIG. 10A along a direction bb′. FIG. 11A is a cross-sectional view of a 3D stacked semiconductor device in a direction parallel to a substrate according to an exemplary embodiment of the present disclosure. FIG. 11B is a cross-sectional view of the structure shown in FIG. 11A along a direction aa′. FIG. 11C is a cross-sectional view of the structure shown in FIG. 11A along a direction bb′.

As shown in FIGS. 2 to 11C, in the present exemplary embodiment, the method for manufacturing the 3D stacked semiconductor device may include the following operations.
S101: Sequentially and alternately depositing a first insulating thin film 10 and a first conductive thin film 11 on a substrate 20 to form a stacked structure, as shown in FIG. 2.

Exemplarily, the first insulating thin film 10 and the first conductive thin film 11 may be deposited using a Chemical Vapor Deposition (CVD) method.

Exemplarily, the substrate may be a silicon substrate.

Exemplarily, the first insulating thin film 10 may be a low-K dielectric layer, that is, a dielectric layer having a dielectric constant K<3.9, including but not limited to a silicon oxide such as silicon dioxide (SiO₂) and the like.

Exemplarily, the first conductive thin film 11 may include, but is not limited to, a multilayer structure composed of titanium nitride (TiN) and tungsten (W). The titanium nitride is provided between the first insulating thin film 10 and tungsten, and may be located only on the side of the tungsten close to the substrate to prevent the tungsten metal from oxidizing influenced by the first insulating thin film 10 containing oxygen such as silicon oxide, and this film layer may be referred to as an anti-oxidation layer. Of course, if the first insulating layer may be a film layer containing no oxygen, it is not required to add the anti-oxidation layer to the first conductive thin film 11.

The stacked structure shown in FIG. 2 includes five layers of the first insulating thin films 10 and four layers of the first conductive thin films 11, which are provided merely as an example. In other embodiments, the stacked structure may include more or fewer layers of the first insulating thin films 10 and the first conductive thin films 11 alternately arranged.
S102: Patterning the first conductive thin film 11 to form a patterned conductive layer 12. The patterned conductive layer 12 may include a bit line 30, a plurality of spaced first sub-portions 21 and a plurality of spaced second sub-portions 22. The bit line 30 connects the first sub-portions 21 and the second sub-portions 22, the plurality of spaced first sub-portions 21 and the plurality of spaced second sub-portions 22 are located on two sides of the bit line 30, respectively, and the bit line 30, the plurality of first sub-portions 21 and the plurality of second sub-portions 22 may form a structure like the Chinese character “ [symbol] ”. The bit line 30 serves as a main trunk of the structure like the Chinese character “ [symbol] ”, and the plurality of first sub-portions 21 and the plurality of second sub-portions 22 serve as branches of the structure like the Chinese character “ [symbol] ”. The first sub-portion 21 may extend along a first direction (direction X in FIG. 3A), the second sub-portion 22 may extend along the first direction, and the bit line 30 may extend along a second direction (direction Y in FIG. 3A). The first sub-portion 21 is subsequently disconnected from the bit line 30 to form a first electrode 51 of a transistor, and the bit line 30 may serve as a second electrode 52 of the transistor, that is, the bit line and the second electrode 52 may be shared. The second sub-portion 22 is subsequently disconnected from the bit line to form a first electrode 51 of another adjacent transistor, and the bit line 30 serves as a second electrode 52 of the transistor, as shown in FIGS. 3A and 3B. FIG. 3A is a cross-sectional view in a direction parallel to the substrate (a cross-sectional view in a region where the conductive layer 12 is located, and cross-sectional views in the direction parallel to the substrate in the following are all cross-sectional views in the region where the conductive layer 12 is located, which is not repeated hereinafter), and FIG. 3B is cross-sectional view in a direction bb′.

Exemplarily, the stacked structure may be etched by a dry etching method, and the conductive layer 12 formed by patterning is then filled with the first insulating thin film in the etched region to isolate different devices.
S103: Patterning the first insulating thin film 10, to remove the first insulating thin film 10 located in a capacitor region 100, expose one end of the first sub-portion 21 away from the bit line 30 (including an end surface and a part of a side surface of the first sub-portion 21), and expose one end of the second sub-portion 22 away from the bit line 30 (including an end surface and a part of a side surface of the second sub-portion 22), so as to form a stacked structure in which the insulating layer 14 and the conductive layer 12 are alternately arranged. The conductive layer 12 includes an electrode pattern which is the same as the pattern of the patterned conductive layer formed in step S102, except that the end of the first sub-portion 21 away from the bit line 30 is exposed and the end of the second sub-portion 22 away from the bit line 30 is exposed. The first insulating thin film located in a gap between the electrode patterns in any adjacent conductive layers forms an isolation layer 15 extending in a direction perpendicular to the substrate 20, as shown in FIGS. 4A and 4B. FIG. 4A is a cross-sectional view in a direction parallel to the substrate (a cross-sectional view in the region where the conductive layer 12 is located), and FIG. 4B is a cross-sectional view in a direction aa′, where the direction aa′ may be parallel to an extending direction of the first sub-portion 21.

Exemplarily, the first insulating thin film 10 in the stacked structure may be laterally etched using a wet etching method.
S104: Sequentially depositing a dielectric thin film and a conductor material on the capacitor region 100 to form a dielectric layer 13 and a second plate 42, respectively, such that the dielectric layer 13 covers the exposed region of the first sub-portion 21 and the exposed region of the second sub-portion 22. That is, the dielectric layer 13 covers an end surface and a part of a side wall of the first sub-portion 21 away from the bit line 30, and the dielectric layer 13 covers an end surface and a part of a side wall of the second sub-portion 22 away from the bit line 30, as shown in FIGS. 5A and 5B. FIG. 5A is a cross-sectional view in a direction parallel to a substrate, and FIG. 5B is a cross-sectional view in a direction aa′.

The dielectric layer 13 serves as a dielectric between the capacitor plates, the second plate 42 serves as one electrode of the capacitor, and the first sub-portion 21 or the second sub-portion 22 serves as the other electrode of the capacitor, that is, the first plate.

Exemplarily, the dielectric thin film and the conductor material may be deposited by Atomic Layer Deposition (ALD) method.

Exemplarily, the dielectric thin film may be a High-K dielectric material, i.e. a dielectric material having a dielectric constant K≥3.9. The High-K dielectric material may include, but is not limited to, at least one of the followings: silicon oxide, aluminum oxide (Al₂O₃), and hafnium oxide and the like.

Exemplarily, the conductor material includes, but is not limited to, at least one of the following: polysilicon, tungsten, titanium nitride.

For example, TiN or the like may be deposited in the capacitor region 100 before the dielectric thin film is deposited, in order to prevent a metal such as tungsten of the conductive layer from being oxidized by the oxygen-containing dielectric thin film such as silicon oxide.
S105: Forming a plurality of through-holes K1.

The step of, forming a plurality of through-holes K1, may include: etching the stacked structure by dry etching to form the plurality of through-holes K1 passing through the plurality of conductive layers 12 in a direction perpendicular to the substrate 20. The entire side walls of the through-holes K1 in the conductive layers 12 exposes each conductive layer 12, that is, the through-holes K1 do not pass through the conductive layer 12 in the direction aa′ and the direction bb′, and the conductive layer 12 with a certain thickness is retained on two sides of the through-holes K1, as shown in FIGS. 6A, 6B, and 6C. FIG. 6A is a cross-sectional view in a direction parallel to a substrate, FIG. 6B is a cross-sectional view in a direction aa′ and FIG. 6C is a cross-sectional view in a direction bb′, where the direction bb′ may be perpendicular to the direction aa′.

The conductive layer 12 retained in the direction bb′ may serve as an etching block layer for the through-hole K1 in the conductive layer 12 in a subsequent etching process. Both the first sub-portion 21 and the second sub-portion 22 are provided with the through-hole K1, and the through-hole K1 may extend in a direction perpendicular to the substrate 20. The through-hole K1 may or may not expose the substrate 20.

For example, when etching the stacked structure by dry etching to form the through-holes K1 in S105, etching is performed using a High Aspect ratio Etch (HAR ET) method.

Exemplarily, an orthographic projection of the through-hole K1 on a plane parallel to the substrate may be square, circular, elliptical, or the like.

Exemplarily, the through-hole K1 in the conductive layer 12 is smaller than an area of the conductive layer 12. For example, the through-hole K1 passing through the first sub-portion 21 in the conductive layer 12 is smaller than an area of the first sub-portion 21, and the through-hole K1 passing through the second sub-portion 22 is smaller than an area of the second sub-portion 22.
S106: Laterally enlarging the through-holes K1 for the first time.

The step of, laterally enlarging the through-holes K1 for the first time, may include: laterally etching the insulating layers in the through-holes K1 such that the through-holes K1 in the conductive layers 12 are smaller than the through-holes K1 in the insulating layers. That is, the through-holes K1 may form a plurality of dumbbell-shaped structures, as shown in FIGS. 7A and 7B. FIG. 7A is a cross-sectional view in the direction aa′ and the direction aa′ here is the same as the direction aa′ shown in FIG. 6A, and FIG. 7B is a cross-sectional view in the direction bb′ and the direction bb′ here is the same as the direction bb′ shown in FIG. 6A.

Exemplarily, wet etching may be performed by selecting an acid solution having a high etching selectivity ratio for the first insulating thin films 10 and the conductive layers 12 to laterally etch the insulating layers by a thickness L in a direction away from the through-holes K1, and the conductive layers 12 are almost not etched due to the high etching selectivity ratio.
S107: Laterally enlarging the through-holes K1 for the second time.

The step of, laterally enlarging the through-holes K1 for the second time, may include: laterally etching the conductive layers 12 in the through-holes K1 until the side walls of the through-holes K1 in the conductive layers 12 simultaneously expose the conductive layers 12 and the first insulating thin films 10. That is, the retained conductive layers 12 in the direction bb′ retained in S106 are etched away (D is greater than d), such that the side walls of the through-holes K1 in the conductive layers 12 in the direction bb′ expose the first insulating thin film 10, and the through-holes K1 in the conductive layers 12 are smaller than the through-holes K1 in the insulating layers, and the through-holes K1 cause the conductive layer 12 to form at least one pair of a first conductive portion and a second conductive portion that are separated from each other. The first conductive portion and the second conductive portion will subsequently serve as the first electrode 51 and the second electrode 52 of the transistor (one of the first electrode 51 and the second electrode 52 is a source electrode and the other of them is a drain electrode), and the first electrode 51 also serves as the first plate 41 of the capacitor, as shown in FIGS. 8A and 8B. FIG. 8A is a cross-sectional view in a direction parallel to a substrate, and FIG. 8B is a cross-sectional view in a direction bb′.

For example, the conductive layers 12 may be etched in a direction away from the through-holes K1 by wet etching, and an acid solution having a high etching selectivity ratio for the conductive layers 12 and the first insulating thin films 10 is selected, such that the side walls of the through-holes K1 in the conductive layers 12 alternately expose the conductive layers 12 and the first insulating thin films 10.

Taking the cross section of the through-holes K1 parallel to the substrate being a square as an example, after step S107, a pore diameter of the through-hole K1 in the conductive layer 12 is D, a pore diameter of the through-hole K1 in the insulating layer is W, and W=D+2*L.
S108: Forming a sacrificial layer in the through-holes K1.

The step of, forming a sacrificial layer in the through-holes K1, includes: laterally etching the isolation layer 15 formed by the exposed first insulating thin film in the through-holes K1, such that the through-holes K1 extend only into the isolation layer 15 between two adjacent through-holes and form an extension portion K2 passing through the isolation layer 15 (the extension portion K2 is a part of the through-hole K1), and filling a sacrificial layer thin film 16 in the extension portion K2 of the through-holes to form a sacrificial layer.

Exemplarily, S108 may include the following operations.
1) Depositing a sacrificial layer thin film 16 on inner walls of the through-holes K1, and filling a second insulating thin film in the through-holes K1.

For example, the sacrificial layer thin film 16 having a relatively small thickness may be deposited on the inner walls of the through-holes K1 formed in S107 by an ALD method, and a second insulating thin film is filled in the remaining space of the through-holes K1. A material of the sacrificial layer thin film 16 may be a nitride, for example, silicon nitride (SiN), silicon carbonitride (SiCN), or the like. A material of the second insulating thin film may be an oxide, for example, silicon oxide (SiO₂) or the like.
2) Etching and removing the sacrificial layer thin film 16 on at least a part of the side walls of the through-holes K1. For example, the sacrificial layer thin film 16 located on the side walls of the through-holes K1 in the direction aa′ can be etched away, such that voids are formed on two sides of the second insulating thin film. The isolation layer 15 formed by the exposed first insulating thin film is laterally etched in the through-holes K1 by the voids, such that the through-holes K1 only extend into the isolation layer 15 between two adjacent through-holes K1 and form an extension portion K2 passing through the isolation layer 15, and the sacrificial layer thin film 16 is filled in the remaining space of the through-holes K1 to form a sacrificial layer 25. Exemplarily, the extension portion K2 may extend in a direction perpendicular to the substrate 20.
3) Etching and removing the second insulating thin film in the through-holes K1, as shown in FIGS. 9A, 9B, and 9C. FIG. 9A is a cross-sectional view in a direction parallel to a substrate, FIG. 9B is a cross-sectional view in a direction aa′, and FIG. 9C is a cross-sectional view in a direction bb′.

The sacrificial layer 25 may serve as a protective layer of a semiconductor layer 23 of a MOS channel region 200 when a semiconductor layer 23 of a side wall of a parasitic MOS region 300 is subsequently etched.
S109: Etching and removing the sacrificial layer 25 on the side walls of the through-holes K1 obtained in the step S108, such that the side walls of the through-holes K1 in the insulating layer expose both the insulating layer and the sacrificial layer 25, and the side walls of the through-holes K1 located in the conductive layer 12 expose the first conductive portion and the second conductive portion of the conductive layer 12 and the sacrificial layer 25.

Exemplarily, wet etching may be employed to remove the sacrificial layer 25 on the side walls of the through-holes K1.
S110: Forming a semiconductor thin film 28, a gate insulating layer 24, and a gate electrode 26.

The step of, forming a semiconductor thin film 28, a gate insulating layer 24, and a gate electrode 26, may include: sequentially depositing a semiconductor thin film 28 and a gate insulating thin film on the side walls of the through-holes K1 obtained in S109, such that the semiconductor thin film 28 is in contact with the first conductive portion and the second conductive portion, and the gate insulating thin film forms the gate insulating layer 24, and filling the gate electrode thin film in the through-holes. The gate electrode thin film forms the gate electrode 26, and the gate electrodes 26 in different layers are connected together to form a word line, as shown in FIGS. 10A, 10B and 10C. FIG. 10A is a cross-sectional view in a direction parallel to a substrate, FIG. 10B is a cross-sectional view in a direction aa′, and FIG. 10C is a cross-sectional view in a direction bb′. At this time, the pore diameter of the through-hole K1 in the parasitic MOS region 300 is larger than the pore diameter of the through-hole K1 in the MOS channel region 200 in the first direction.

For example, the semiconductor thin film and the gate insulating thin film surrounding the semiconductor thin film may be sequentially deposited on the side wall of the through-hole K1 by ALD method.

In some embodiments, a material of the semiconductor thin film may include one or more of the following: indium gallium zinc oxide (InGaZnO), indium zinc oxide (InZnO), indium gallium oxide (InGaO), indium tin oxide (InSnO), indium gallium tin oxide (InGaSnO), indium gallium zinc tin oxide (InGaZnSnO), indium oxide (InO), tin oxide (SnO), zinc tin oxide (ZnSnO, ZTO), indium aluminum zinc gold oxide (InAlZnO), zinc oxide (ZnO), indium gallium silicon oxide (InGaSiO), indium tungsten oxide (InWO, IWO), titanium oxide (TiO), zinc oxynitride (ZnON), magnesium zinc oxide (MgZnO), zirconium indium zinc oxide (ZrInZnO) , hafnium indium zinc oxide (HfInZnO), tin indium zinc oxide (SnInZnO), aluminum tin indium zinc oxide (AlSnInZnO), silicon indium zinc oxide (SiInZnO), aluminum zinc tin oxide (AlZnSnO), gallium zinc tin oxide (GaZnSnO), zirconium zinc tin oxide (ZrZnSnO), and other materials, as long as a leakage current of the transistor can meet requirements, which can be adjusted according to actual situations.

Exemplarily, the gate insulating thin film may be a High-K dielectric material, and exemplarily, for example, may include, but is not limited to, at least one of the following: hafnium oxide (HfO₂), alumina (Al₂O₃), hafnium aluminum oxide (HfAlO), hafnium lanthanum oxide (HfLaO), zirconium oxide (ZrO₂) and other high K materials.

Exemplarily, the gate electrode thin film may be deposited by ALD.

In an exemplary embodiment, a material of the gate electrode may be one or more of the following different types of materials.

For example, the material of the gate electrode includes a metal, such as tungsten, aluminum, titanium, copper, nickel, platinum, ruthenium, molybdenum, gold, iridium, rhodium, tantalum, cobalt and the like; or it may be a metal alloy containing metals of these metals mentioned above.

Alternatively, the material of the gate electrode may be a metal oxide, a metal nitride, a metal silicide, a metal carbide, etc., such as tin-doped indium oxide (ITO), indium-doped zinc oxide (IZO), indium oxide (InO), aluminum-doped zinc oxide (AZO), iridium oxide (IrOx), ruthenium oxide (RuOx) and other metal oxide conductive materials; for example, titanium nitride (TiN), tantalum nitride (TaN), tungsten nitride (WN), titanium aluminum nitride (TiAlN) and other metal nitride materials.

Alternatively, the material of the gate electrode may also be a polysilicon material. The material of the gate electrode may also be a conductive doped semiconductor, such as, conductive doped silicon, conductive doped germanium, conductive doped silicon germanium, etc., or another material that shows conductivity, etc.

For example, a thickness of the semiconductor layer 23 along a radial direction of the through-hole K1 may be 3 nm±10%, and a thickness of the gate insulating layer 24 along the radial direction of the through-hole K1 may be 10 nm±10%, but this is merely an example. The thicknesses of the semiconductor layer 23 and the gate insulating layer 24 may be other values.
S111: Removing the semiconductor thin film 28 in the through-holes K1 in the parasitic MOS region 300, the remaining semiconductor thin film 28 constituting a semiconductor layer 23 of the transistor.

Exemplarily, the step of, removing the semiconductor thin film 28 in the through-holes K1 in the parasitic MOS region 300, may include the following operations.
1) Vertically etching the sacrificial layer 25 in the extension portion K2 of the through-hole K1 downward from the outside of the through-hole K1 by a dry etching method. Since the parasitic MOS region 300 has a convex structure, after the sacrificial layer 25 in the extension portion K2 is etched away, the semiconductor thin film 28 located in the parasitic MOS region 300 is exposed first. That is, the side wall of the through-hole K1 in the insulating layer will expose the semiconductor thin film 28, but at this time the sacrificial layer 25 in the through-hole K1 in the conductive layer is not completely etched, therefore, the side wall of the through-hole K1 in the conductive layer exposes the sacrificial layer 25.
2) Removing the semiconductor thin film 28 in the through-hole K1 in the insulating layer by a dry etching or wet etching method, that is, removing the semiconductor thin film 28 located in the parasitic MOS region. Since the channel region is recessed, the semiconductor thin film 28 located in the channel region is still covered by the sacrificial layer 25, and the semiconductor thin film 28 located in the channel region is not etched with the protection of the sacrificial layer 25, thereby forming the semiconductor layer 23 of the transistor, and obtaining the 3D stacked semiconductor device as shown in FIGS. 11A, 11B and 11C. FIG. 11A is a cross-sectional view in a direction parallel to a substrate, FIG. 11B is a cross-sectional view in a direction aa′, and FIG. 11C is a cross-sectional view in a direction bb′.

Exemplarily, the method for manufacturing the 3D stacked semiconductor device may further include: after S111, performing the following steps.
S112: Etching and removing the remaining sacrificial layer 25 in the through-hole K1 in the conductive layer, and filling a third insulating thin film 27 in the space vacated by the etching of the sacrificial layer 25; alternatively, directly filling the third insulating thin film 27 in the space vacated by S111 without removing the remaining sacrificial layer 25 in the through-hole K1 in the conductive layer. At this time, the side walls of the through-holes K1 in the conductive layers alternately expose the sacrificial layer 25 and the semiconductor layer 23.

Exemplarily, the third insulating thin film 27 may be deposited using an ALD method. A material of the third insulating thin film 27 may be a low-K material, that is, a material having a dielectric constant K<3.9, and the third insulating thin film made of the low-K material may reduce parasitic capacitance between adjacent transistors in a same layer. In other embodiments, the material of the third insulating thin film 27 may also be an oxide, for example, silicon oxide.

According to the scheme provided by the embodiments of the present disclosure, by etching away the semiconductor layer between the layers, the MOS parasitic capacitance can be effectively reduced or eliminated, the stability of the device can be increased, and the effective length of the channel (the length of the semiconductor layer between the first electrode and the second electrode) is not affected.

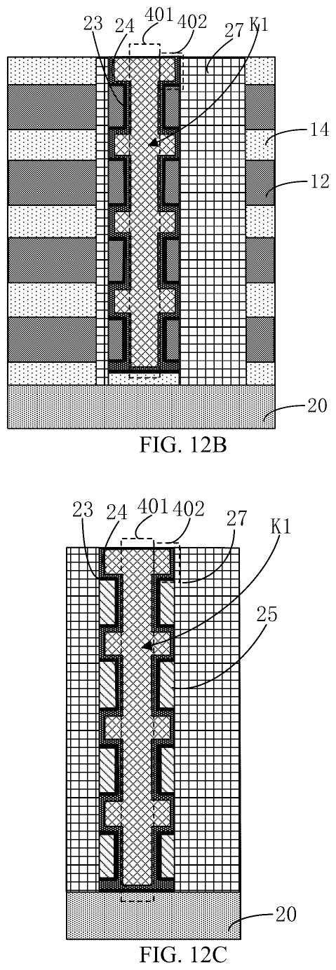

An embodiment of the present disclosure provides a 3D stacked semiconductor device including a plurality of transistors and a word line 40, as shown in FIGS. 12A, 12B, and 12C.

The plurality of transistors are distributed in different layers, stacked along a direction perpendicular to the substrate 20, and periodically distributed. The transistor includes a gate electrode 26, a semiconductor layer 23 surrounding a side wall of the gate electrode 26, and a gate insulating layer 24 disposed between the side wall of the gate electrode 26 and the semiconductor layer 23. The gate electrode 26 extends in a direction perpendicular to the substrate 20. The plurality of semiconductor layers 23 of the plurality of transistors are arranged at intervals and disconnected. And, the word line 40 passes through different layers, and the word line 40 includes a word line body 401 and a protrusion 402 disposed on the word line body. The word line body 401 extends along a direction perpendicular to the substrate 20, and the protrusion 402 of the word line 40 extends between the semiconductor layers 23 arranged at intervals. The gate electrode 26 of each transistor is a part of the word line 40, and the plurality of semiconductor layers 23 are distributed in different regions of a side wall of the word line body.

The semiconductor layers of the transistors of at least some adjacent layers of the 3D stacked semiconductor device provided by the present embodiment are arranged at intervals, which can reduce or eliminate parasitic MOS between at least some of the transistors and improve device stability.

Exemplarily, the semiconductor layers 23 of the transistors in different layers are arranged at intervals in a direction perpendicular to the substrate. That is, the semiconductor layers 23 of the transistors in all adjacent layers are arranged at intervals in a direction perpendicular to the substrate, such that parasitic MOS between all adjacent layers can be eliminated and device stability can be improved.

Exemplarily, the gate electrode extends only in a direction perpendicular to the substrate. The gate electrode includes a side surface and end surfaces at upper and lower ends. The side surface is perpendicular to the substrate as a whole, or a partial region of the side wall corresponding to the semiconductor layer 23 that acts for a gate electrode control (i.e., a side wall of an effective gate electrode) has a film layer that is perpendicular to the substrate. Regions where bending may exist locally during actual manufacturing of the product are also included in the cases described above in this disclosure.

The semiconductor layer 23 surrounding the gate electrode 26 and insulated from the gate electrode 26 can be understood as one film layer having two opposite main surfaces and two end surfaces. A surface area of the two opposite main surfaces is larger than a surface area of the end surfaces. For example, the semiconductor layer 23 extends along the side wall of the gate electrode 26, its film layer thickness direction is a direction parallel to the substrate, a length of the film layer extending up and down the side wall of the gate electrode 26 is a height of the film layer, and a length surrounding the gate electrode 26 is a width of the film layer.

Exemplarily, the semiconductor layer may extend on a side wall of the gate electrode to form a ring-shaped semiconductor layer extending in a direction perpendicular to the substrate. This includes cases where the semiconductor layer extends only in a direction perpendicular to the substrate, or where the main body of the semiconductor layer extends in a direction perpendicular to the substrate, and a horizontal portion extending in a horizontal direction and facing the gate electrode may exist at an end.

Herein, “surrounding” may be understood as partially or completely surrounding a gate electrode. In some embodiments, the “surrounding” may be overall entirely surrounding, and a cross-section of the semiconductor layer 23 after the surrounding is in a shape of a closed ring. The cross-section is taken along a direction parallel to the substrate. In some embodiments, the “surrounding” may be partially surrounding, the cross-section after the surrounding is not closed, but assumes a ring shape, for example, the ring shape having an opening.

For example, different regions of the word line 40 extending in the direction perpendicular to the substrate have a same material composition, which can be understood as being formed using a same film layer fabrication process. The same material composition can be understood as the main elements tested in the material being the same, for example, they are all made of transparent conductive materials such as metal or ITO, but the atomic ratio of different regions is not limited. Exemplarily, the transistor may further include a gate insulating layer 24 surrounding the side wall of the gate electrode 26.

Exemplarily, transistors in different layers may share a ring-shaped gate insulating layer extending in a direction perpendicular to the substrate.

Exemplarily, gate insulating layers of transistors in at least some adjacent layers may be arranged at intervals in a direction perpendicular to the substrate.

Exemplarily, gate insulating layers of transistors in different layers are arranged at intervals in a direction perpendicular to the substrate.

Exemplarily, the semiconductor layer may be of a fully-surrounding type, fully surrounding the side wall of the gate electrode, i.e. a cross-section of the semiconductor layer in a direction parallel to the substrate is closed ring shape. Exemplarily, the semiconductor layer is ring-shaped, and the ring shape is adapted to the outer contour shape of the cross section of the gate electrode 6. Exemplarily, the cross-section of the gate electrode is, for example, square or the like.

Exemplarily, the 3D stacked semiconductor device may further include: insulating layers 14 and conductive layers 12 alternately and sequentially distributed from bottom to top in a direction perpendicular to the substrate; and through-holes K1 passing through the insulating layers 14 and the conductive layers 12. The word line 40, the gate insulating layer 24 surrounding a side wall of the word line 40, and the plurality of semiconductor layers 23 surrounding different regions of a side wall of the gate insulating layer 24 and extending in a direction perpendicular to the substrate are sequentially distributed from inner to outer in the through-holes K1.

The plurality of semiconductor layers 23 are disconnected at side walls of the insulating layers 14, and the protrusions of the word line 40 extend into the insulating layer 14.

The conductive layer 12 includes a first conductive portion and a second conductive portion spaced apart from each other. The first conductive portion and the second conductive portion serve as a first electrode 51 and a second electrode 52 of the transistor, respectively. One of the first electrode 51 and the second electrode 52 is a source electrode, and the other of them is a drain electrode, and each of the semiconductor layers 23 is in contact with the source electrode and the drain electrode of the conductive layer 12 in a corresponding layer.

Exemplarily, a pore diameter of a first region of the through-hole K1 corresponding to the conductive layer 12 is smaller than a pore diameter of a second region of the through-hole corresponding to the insulating layer 14.

Only the side walls of the insulating layers 14 are exposed in the through-holes K1, and side walls and partial regions of upper and lower surfaces of the conductive layers 12 are exposed in the through-holes K1.

The semiconductor layers 23 are distributed at least on the side walls of the conductive layers 12.

Exemplarily, the gate electrode is a part of the word line body, and the semiconductor layer at least surrounds between two adjacent protrusions. Exemplarily, the transistor includes a first electrode and a second electrode, and the first electrode and the second electrode are a source electrode and a drain electrode of the transistor, respectively, and the semiconductor layer extends onto at least a part of a side wall of the first electrode of the transistor.

Exemplarily, a channel between the source electrode and the drain electrode of one of the transistors is a horizontal channel.

Horizontal channel means that a transport direction of carriers in the channel is in a plane parallel to the substrate, but it is not limited that the transport direction of the carriers must be one direction. In practical applications, the transport direction of the carriers extends in one direction as a whole, but locally, it is related to a shape of the semiconductor layer. In other words, the horizontal channel does not mean that it must extend along one direction in the horizontal plane, but may extend along different directions. For example, when the semiconductor layer is ring-shaped, the source contact region and the drain contact region on the ring-shaped semiconductor layer are a portion of the ring shape, and in this case, carriers extend along one direction from the source contact region to the drain contact region as a whole, but may not be in one direction locally. Of course, the transport direction of the carriers in a plane parallel to the substrate is also a macroscopic concept, and is not limited to being absolutely parallel to the substrate. The present disclosure protects the channel between the first electrode and the second electrode as a channel not perpendicular to the substrate.

Exemplarily, as shown in FIG. 12A, the transistors in a same layer are arranged in an array along a first direction and a second direction, the first electrode 51 and the second electrode 52 of the transistor may extend along the first direction, and the second direction may be perpendicular to the first direction. Exemplarily, as shown in FIG. 12A, the 3D stacked semiconductor device may further include a bit line 30 connected to the second electrodes 52 of a column of transistors in the same layer, and the bit line 30 may extend along the second direction.

Exemplarily, the second electrodes 52 of two adjacent columns of transistors in the same layer may be connected to a same bit line 30. The second electrodes 52 of two adjacent columns of transistors in the same layer and the bit line 30 may have an integral structure. Exemplarily, the second electrode 52 of the transistor may be a part of the bit line 30 to which the second electrode 52 is connected.

Exemplarily, as shown in FIGS. 12A, 12B, and 12C, the 3D stacked semiconductor device may further include a third insulating thin film 27 disposed between two adjacent transistors distributed along the second direction. The material of the third insulating thin film 27 may be a low-K material, that is, a material having a dielectric constant K<3.9, which can reduce the parasitic capacitance between two adjacent transistors distributed along the second direction.

Exemplarily, as shown in FIG. 12C, the 3D stacked semiconductor device may further include a sacrificial layer 25, and the sacrificial layer 25 can be disposed on a side wall of the semiconductor layer 23.

An embodiment of the present disclosure provides a 3D memory, as shown in FIGS. 11A, 11B, and 11C. In an exemplary embodiment, the 3D memory includes: a plurality of layers of memory cells stacked in a direction perpendicular to a substrate and a word line 40, and the word line 40 passes through the memory cells in different layers.

The memory cell includes a transistor, and the transistor includes a first electrode 51, a second electrode 52, a gate electrode 26 extending in a direction perpendicular to the substrate, and a semiconductor layer 23 surrounding the gate electrode 26 and insulating from the gate electrode 26. The semiconductor layers 23 of the transistors of the memory cells in at least some adjacent layers are arranged at intervals in a direction perpendicular to the substrate.

The word line 40 includes a word line body 401 and protrusions 402 arranged on the word line body. The word line body 401 extends in a direction perpendicular to the substrate, the semiconductor layers 23 arranged at intervals are disconnected from each other, and the protrusions 402 of the word line 40 extend between the semiconductor layers 23 arranged at intervals.

The semiconductor layers of the transistors in at least some adjacent layers of the 3D memory provided by the present embodiment are arranged at intervals, which can reduce or eliminate parasitic MOS between at least some transistors located in different layers, and improve device stability.

Exemplarily, the semiconductor layers 23 of the transistors of the memory cells in different layers are arranged at intervals in a direction perpendicular to the substrate. That is, the semiconductor layers 23 of the transistors of the memory cells in all adjacent layers are arranged at intervals in a direction perpendicular to the substrate, such that parasitic MOS between all adjacent layers can be eliminated and device stability can be improved.

For example, the first electrode 51 and the second electrode 52 of the same transistor may be located in a same conductive film layer in the direction perpendicular to the substrate. It can be understood that the first electrode 51 and the second electrode 52 are located in a same metal film layer, and are formed by patterning one conductive film layer, and the conductive film layer is approximately parallel to an upper surface of the substrate. The first electrode 51 and the second electrode 52 may be arranged in a same layer. That is, the first electrode 51 and the second electrode 52 can be formed simultaneously by a same patterning process, but the embodiment of the present disclosure is not limited thereto, and the first electrode 51 and the second electrode 52 can be respectively manufactured by different patterning processes.

For example, the first electrode 51 or the second electrode 52 of different transistors may be located in different conductive film layers.

Exemplarily, stacked transistors in different layers may share one word line 40 extending in a direction perpendicular to the substrate.

Exemplarily, the semiconductor layers 23 corresponding to transistors in different layers may be located on the side wall of the word line 40 and located in different regions extending in a direction perpendicular to the substrate, respectively.

Exemplarily, the gate electrodes 26 of the transistors in different layers are part of the word line 40, and the word line 40 is exposed between the semiconductor layers 23 arranged at intervals, as shown in FIGS. 11B and 11C.

Exemplarily, as shown in FIGS. 11B and 11C, an insulating layer is exposed between the semiconductor layers 23 arranged at intervals, the insulating layer is a gate insulating layer 24 located between the gate electrode and the semiconductor layer 23, and the gate insulating layers 24 of the transistors in a same column in different layers have an integral structure. According to the scheme provided by the present embodiment, the first electrode 51 and the gate electrode 26 are isolated by the gate insulating layer 24, such that the first electrode 51 may be prevented from being exposed due to over etching, which would otherwise lead to a short circuit between the first electrode 51 and the gate electrode 26.

Exemplarily, the gate electrode is a part of the word line body, and the semiconductor layer at least surrounds between two adjacent protrusions.

Exemplarily, as shown in FIGS. 11A and 11B, the memory cells in a same layer form an array distributed along a first direction and a second direction, respectively, and the memory cells in each layer further include a bit line 30 connected to the second electrode 52 of the transistor in a same layer and a same column. FIG. 11A shows that each layer includes three rows and two columns of storage cells, but the embodiment of the present disclosure is not limited thereto, and each layer may include other rows and columns of storage cells, for example, may include only one storage cell. The first direction may be parallel to the substrate, the second direction may be parallel to the substrate, and the first direction intersects with the second direction. In some embodiments, the first direction and the second direction may be perpendicular to each other.

Exemplarily, each layer may include a plurality of memory cells, but embodiments of the present disclosure are not limited thereto, and each layer may include one memory cell.

Exemplarily, the second electrodes 52 of the transistors in two adjacent columns of memory cells are connected to a same bit line 30. The second electrodes 52 of two adjacent columns of transistors in a same layer and the bit line 30 may have an integral structure. Exemplarily, the second electrode 52 of the transistor may be a part of the bit line 30 to which the second electrode 52 is connected. Exemplarily, the bit line 30 may extend in the second direction. Exemplarily, the first electrode 51 may extend in the first direction. Exemplarily, the 3D memory may further include a data storage element. Exemplarily, the data storage element is, for example, a capacitor, i.e. forms a 1T1C storage structure. However, embodiments of the present disclosure are not limited thereto, and they can also form a 2T0C storage structure in combination with other transistors, and so on. Exemplarily, the capacitor may include a first plate 41 and a second plate 42, and the first plate 41 is connected to the first electrode 51. Exemplarily, the first plate 41 and the first electrode 51 may have an integral structure.

Exemplarily, the second plates 42 of the capacitors of the same column in different layers may be connected into an integral structure. As shown in FIG. 11B, the second plates 42 of the capacitors of the first column in different layers are connected into an integral structure. The second plates 42 of the capacitors of the second columns in different layers are connected into an integral structure, that is, the capacitors of the same columns in different layers share the same plate as the second plate 42.

Exemplarily, the capacitor may further include a dielectric layer 13 disposed between the first plate 41 and the second plate 42.

Exemplarily, projections of the first electrodes of adjacent transistors in a direction perpendicular to the substrate overlap in the direction perpendicular to the substrate, projections of the second electrodes of the adjacent transistors in the direction perpendicular to the substrate overlap in the direction perpendicular to the substrate, and projections of the gate electrodes of the adjacent transistors in the direction perpendicular to the substrate overlap in the direction perpendicular to the substrate. According to the scheme provided by the present embodiment, in the process, the first electrode and the second electrode which are stacked in multiple layers can be formed by relatively stacking the conductive layers and the insulating layers through a mask, which simplifies the process. In addition, the structure of the 3D memory can be made more compact.

Exemplarily, as shown in FIGS. 11A, 11B, and 11C, the 3D memory may further include a third insulating thin film 27 disposed between two adjacent transistors distributed along the second direction. The material of the third insulating thin film 27 may be a low-K material, such as silicon oxide or other material, or air, which may reduce the parasitic capacitance between two adjacent transistors distributed in the second direction.

Exemplarily, as shown in FIG. 11C, the 3D stacked semiconductor device may further include a sacrificial layer 25, and the sacrificial layer 25 can be disposed on a side wall of the semiconductor layer 23.

The 3D memory described above may be a 1T1C memory structure composed of a transistor and a capacitor, or it can form a 2T0C memory structure in combination with other transistors, and the like.

Exemplarily, the 3D stacked semiconductor device and the 3D memory can be obtained by the method for manufacturing the 3D stacked semiconductor device provided by the embodiments of the present disclosure.

An embodiment of the present disclosure provides an electronic device including the 3D stacked semiconductor device as provided by the above embodiments of the present disclosure, or the 3D memory as provided by the above embodiments of the present disclosure.

Exemplarily, the electronic device may be a storage device, a smart phone, a computer, a tablet, an artificial intelligence device, a wearable device, or a mobile power supply, or the like. The storage device may include a memory in a computer or the like, which is not limited here. Although implementations disclosed in the present disclosure are described above, the described contents are only implementations used for facilitating understanding of the present disclosure, but are not intended to limit the present disclosure. Without departing from the spirit and scope disclosed in the present disclosure, any person skilled in the art to which the present disclosure pertains may make any modifications and changes in the implementation form and details, however the protection scope of the present disclosure shall still be defined by the appended claims.

1. A method for manufacturing a 3D stacked semiconductor device, wherein the 3D stacked semiconductor device comprises a plurality of transistors distributed in different layers, stacked in a direction perpendicular to a substrate and distributed periodically, and a word line; a transistor of the plurality of transistors comprises a gate electrode, a semiconductor layer surrounding a side wall of the gate electrode, and a gate insulating layer disposed between the side wall of the gate electrode and the semiconductor layer;
the method for manufacturing the 3D stacked semiconductor device comprises:
forming a stacked structure composed of insulating layers and conductive layers that are alternately stacked on the substrate; wherein the conductive layers comprise an electrode pattern, the electrode pattern comprises a bit line to be formed and a plurality of branches located on at least one side of the bit line, each branch comprises a first electrode and a second electrode of the transistor; a gap between electrode patterns of any adjacent conductive layers is filled with an isolation layer;
forming through-holes passing through the stacked structure by etching, such that the through-holes in the conductive layers are smaller than the through-holes in the insulating layers;
laterally etching the conductive layers in the through-holes to disconnect the first electrode and the second electrode of each transistor;
laterally etching the isolation layer exposed in the through-holes such that the through-holes extend only into the isolation layer between two adjacent through-holes and form an extension portion passing through the isolation layer, and filling a sacrificial layer in the extension portion of the through-holes;
sequentially depositing a semiconductor thin film and the gate insulating layer on side walls of the through-holes, and filling the word line in the through-holes; and
etching the sacrificial layer in the extension portion of the through-holes in a region between two adjacent through-holes, such that the side walls of the through-holes alternately expose the semiconductor thin film and the sacrificial layer in the direction perpendicular to the substrate; and etching and removing the semiconductor thin film exposed from the side walls of the through-holes, such that the remaining semiconductor thin film constitutes the semiconductor layer of the transistor.

2. The method for manufacturing the 3D stacked semiconductor device according to claim 1, wherein the step of, forming the stacked structure composed of the insulating layers and the conductive layers that are alternately stacked on the substrate, comprises:
providing the substrate, sequentially and alternately depositing a first insulating thin film and a conductive thin film on the substrate, and forming the stacked structure by patterning;
wherein the stacked structure comprises a stack of the insulating layers and the conductive layers that are alternately disposed;
wherein the branches of the electrode pattern comprise a plurality of spaced first sub-portions and a plurality of spaced second sub-portions, the plurality of spaced first sub-portions and the plurality of spaced second sub-portions are respectively located on two sides of the bit line and connected to the bit line; one end of a first sub-portion of the plurality of first sub-portions away from the bit line is exposed, one end of a second sub-portion of the plurality of second sub-portions away from the bit line is exposed, the first sub-portions and the second sub-portions are subsequently disconnected from the bit line to form the first electrodes of transistors, and the bit line is shared as the second electrodes of the transistors; and
the isolation layer is formed by the first insulating thin film and extends in the direction perpendicular to the substrate.

3. The method for manufacturing the 3D stacked semiconductor device according to claim 2, wherein the step of, forming the through-holes passing through the stacked structure by etching, such that the through-holes in the conductive layers are smaller than the through-holes in the insulating layers, comprises:
etching the stacked structure to form the through-holes passing through the conductive layers of the stacked structure, such that entire side walls of the through-holes in the conductive layers expose only the conductive layers; and
laterally etching the insulating layers in the through-holes such that the through-holes in the conductive layers are smaller than the through-holes in the insulating layers.

4. The method for manufacturing the 3D stacked semiconductor device according to claim 2, wherein the step of, laterally etching the conductive layers in the through-holes to disconnect the first electrode and the second electrode of each transistor, comprises:
laterally etching the conductive layers in the through-holes, such that the side walls of the through-holes in each conductive layer expose the conductive layer and the first insulating thin film simultaneously, wherein the through-holes cause the conductive layers to form at least one pair of a first conductive portion and a second conductive portion separated from each other, and the first conductive portion and the second conductive portion respectively serve as the first electrode and the second electrode of the transistor.

5. The method for manufacturing the 3D stacked semiconductor device according to claim 4, wherein the step of, laterally etching the isolation layer exposed in the through-holes such that the through-holes extend only into the isolation layer between two adjacent through-holes and form the extension portion passing through the isolation layer, and filling the sacrificial layer in the extension portion of the through-holes, comprises:
depositing a sacrificial layer thin film on inner walls of the through-holes and filling a second insulating thin film in the through-holes;
etching and removing the sacrificial layer thin film on at least a part of the side walls of the through-holes and laterally etching the isolation layer formed by the first insulating thin film exposed in the through-holes, such that the through-holes extend only into the isolation layer between two adjacent through-holes and form the extension portion passing through the isolation layer, and filling the sacrificial layer thin film in the through-holes to form the sacrificial layer; and
etching and removing the second insulating thin film in the through-holes, and removing the sacrificial layer on the side walls of the through-holes, such that the side walls of the through-holes in the insulating layers expose the insulating layers and the sacrificial layer simultaneously, and the side walls of the through-holes in the conductive layers expose the first conductive portion and the second conductive portion of the conductive layers and the sacrificial layer.

6. The method for manufacturing the 3D stacked semiconductor device according to claim 2, further comprising, before etching the stacked structure to form the through-holes, performing the following process:
sequentially depositing a dielectric layer and a second plate on the exposed end of the first sub-portion and the exposed end of the second sub-portion, wherein the dielectric layer covers the exposed end of the first sub-portion and the exposed end of the second sub-portion, the second plate covers the dielectric layer, and the first sub-portion or the second sub-portion and the second plate constitute a capacitor.

7. The method for manufacturing the 3D stacked semiconductor device according to claim 1, wherein the step of, sequentially depositing the semiconductor thin film and the gate insulating layer on the side walls of the through-holes, and filling the word line in the through-holes, comprises:
sequentially depositing the semiconductor thin film and a gate insulating thin film on the side walls of the through-holes, the semiconductor thin film being in contact with the first electrode and the second electrode of the transistor, and filling a gate electrode thin film in the through-holes, the gate electrode thin film forming the word line;
and, the step of, etching the sacrificial layer in the extension portion of the through-holes in the region between two adjacent through-holes, such that the side walls of the through-holes alternately expose the semiconductor thin film and the sacrificial layer in the direction perpendicular to the substrate; and etching and removing the semiconductor thin film exposed from the side walls of the through-holes, such that the remaining semiconductor thin film constitutes the semiconductor layer of the transistor, comprises:
etching the sacrificial layer in the extension portion of the through-holes in the region between two adjacent through-holes, such that the side walls of the through-holes in the insulating layers expose the semiconductor thin film, and the side walls of the through-holes in the conductive layers expose the sacrificial layer; and etching and removing the semiconductor thin film in the through-holes in the insulating layers, such that the remaining semiconductor thin film between adjacent insulating layers constitutes the semiconductor layer of the transistor, semiconductor layers corresponding to two adjacent transistors are disconnected from each other, and the gate insulating thin film forms the gate insulating layer of each transistor.

8. The method for manufacturing the 3D stacked semiconductor device according to claim 3, wherein the step of, etching the stacked structure to form the through-holes passing through the conductive layers of the stacked structure, comprises:
dry-etching the stacked structure to form the through-holes passing through the conductive layers of the stacked structure, such that the entire side walls of the through-holes in the conductive layers exposes only the conductive layers.

9. The method for manufacturing the 3D stacked semiconductor device according to claim 3, wherein the step of, laterally etching the insulating layers in the through-holes, comprises:
laterally etching the insulating layers in the through-holes by wet etching, such that the through-holes in the conductive layers are smaller than the through-holes in the insulating layers.

10. The method for manufacturing the 3D stacked semiconductor device according to claim wherein the step of, laterally etching the conductive layers in the through-holes, comprises:
laterally etching the conductive layers in the through-holes by wet etching to disconnect the first electrode and the second electrode of each transistor.

11. A 3D stacked semiconductor device obtained by the manufacturing method according to claim 1;
wherein the gate electrode extends in the direction perpendicular to the substrate; a plurality of semiconductor layers of the plurality of transistors are arranged at intervals and disconnected; and
the word line passes through the different layers, the word line comprises a word line body and protrusions arranged on the word line body, the word line body extends in the direction perpendicular to the substrate, the protrusions of the word line extend between the semiconductor layers arranged at intervals; the gate electrode of each transistor is a part of the word line, and the plurality of semiconductor layers are distributed in different regions of a side wall of the word line body.

12. The 3D stacked semiconductor device according to claim 11, further comprising:
the insulating layers and the conductive layers alternately and sequentially distributed from bottom to top in the direction perpendicular to the substrate; and
the through-holes passing through the insulating layers and the conductive layers, wherein the word line, the gate insulating layer surrounding a side wall of the word line, and the plurality of semiconductor layers surrounding different regions of a side wall of the gate insulating layer and extending in the direction perpendicular to the substrate are sequentially distributed from inner to outer in the through-holes;
wherein the plurality of semiconductor layers are disconnected at side walls of the insulating layers, and the protrusions of the word line extend into the insulating layers; and
the conductive layers comprise a first conductive portion and a second conductive portion spaced apart from each other, the first conductive portion and the second conductive portion respectively serve as a source electrode and a drain electrode of the transistor, and each semiconductor layer is in contact with a source electrode and a drain electrode of a conductive layer in a corresponding layer.

13. The 3D stacked semiconductor device according to claim 12, wherein a pore diameter of a first region of the through-holes corresponding to the conductive layers is smaller than a pore diameter of a second region of the through-holes corresponding to the insulating layers;
only side walls of the insulating layers are exposed in the through-holes, and side walls and partial regions of upper and lower surfaces of the conductive layers are exposed in the through-holes; and
the semiconductor layers are distributed at least on the side walls of the conductive layers.

14. The 3D stacked semiconductor device according to claim 12, wherein the gate electrode is a part of the word line body, and the semiconductor layer at least surrounds between two adjacent protrusions.

15. The 3D stacked semiconductor device according to claim 11, wherein the transistor comprises the first electrode and the second electrode, the first electrode and the second electrode respectively serve as a source electrode and a drain electrode of the transistor, and a semiconductor layer of the plurality of semiconductor layer extends onto at least a part of a side wall of the first electrode of the transistor.

16. The 3D stacked semiconductor device according to claim 12, wherein a channel between the source electrode and the drain electrode of one of the transistors is a horizontal channel.

17. A 3D memory obtained by the manufacturing method according to claim 1;
wherein the 3D memory comprises a plurality of layers of memory cells stacked in the direction perpendicular to the substrate, and the word line passes through the memory cells in different layers;
wherein the memory cells comprise the transistors; and semiconductor layers of the transistors of the memory cells in at least a part of adjacent layers are arranged at intervals in the direction perpendicular to the substrate; and
the word line comprises a word line body and protrusions arranged on the word line body, the word line body extends in the direction perpendicular to the substrate, the semiconductor layers arranged at intervals are disconnected from each other, and the protrusions of the word line extend between the semiconductor layers arranged at intervals.

18. The 3D memory according to claim 17, wherein an insulating layer is exposed between the semiconductor layers arranged at intervals, the insulating layer is the gate insulating layer located between the gate electrode and the semiconductor layers, and gate insulating layers of the transistors in a same column in the different layers have an integral structure.

19. The 3D memory according to claim 17, wherein the gate electrode is a part of the word line body, and the semiconductor layer at least surrounds between two adjacent protrusions.

20. An electronic device comprising the 3D stacked semiconductor device according to claim 11.
